(19) United States
(12) Patent Application Publication
(10) Pub. No.: US 2006/0013148 A1
(43) Pub. Date: Jan. 19, 2006

(54) Method and apparatus for executing a communication session between two terminals

(76) Inventors: Bo Burman, Upplands Vasby (SE); Torbjorn Einarsson, Stockholm (SE)

Correspondence Address: NIXON & VANDERHYE, PC, 901 NORTH GLEBE ROAD, 11TH FLOOR, ARLINGTON, VA, 22203, US

(21) Appl. No.: 11/158,339

(22) Filed: Jun. 22, 2005

(30) Foreign Application Priority Data
Jul. 5, 2004 (SE) 0401757-0

(51) Int. Cl. G01R 31/08

(52) U.S. Cl. 370/252

(57) ABSTRACT

A method and apparatus for determining session parameters for a communication session between a first terminal (A) and a second terminal (B). At least the first terminal has stored at least one default set of session parameters. An identifier (404) corresponding to a proposed default set of session parameters is sent from the first terminal to the second terminal. Then, it is determined whether the second terminal accepts the proposed default set of session parameters or not. If accepted (406), the proposed default set of session parameters is retrieved in order to execute the session (408). Otherwise, the terminals fall back to a regular session setup procedure. In this way, delays and bandwidth consumption can be substantially reduced by using a minimum of messaging between the two terminals.

### TECHNICAL FIELD

The present invention relates generally to a method and apparatus for executing a communication session between two terminals, requiring the determination of session parameters. In particular, the invention is concerned with simplifying the procedure for determining parameters necessary for that session.

### BACKGROUND OF THE INVENTION AND PRIOR ART

Fixed and mobile telephones have so far been used mainly for making voice calls. The service of communicating limited text messages between mobile terminals, such as SMS (Short Message Service) messages, is also available. These are fairly straightforward telecommunication services which use well-established technologies under more or less fixed prerequisites. In the standardized communication protocols used for calls between fixed and/or mobile terminals, predefined sets of communication rules and parameters are typically used, which are known by the terminals and within their capabilities. Hence, it is presumed that both a calling terminal and a called terminal are capable of conducting the call based on such fixed communication parameters valid for each terminal. Therefore, a traditional call, such as a simple voice call, can be established quite fast since both terminals “know” in beforehand what parameters to use, e.g., concerning transmission and encoding schemes. No procedure is thus needed to establish which rules and parameters to use in order to execute such a call.

A multitude of different telephony services are constantly developed, which are possible to employ in particular as new technologies for communication are introduced, providing greater network capacity and higher transmission rates. For example, GPRS (General Packet Radio Service) and WCDMA (Wideband Code Division Multiple Access) technologies are currently emerging for enabling wireless telephony services requiring a wide range of different data rates.

Some new services involve real-time transmission of video information as well as audio information, and may further include the transmission of added data representing text, documents, images, audio files and video files in various different formats and combinations. Such services are generally referred to as “multimedia” services, which term will be used in this description to represent any telephony services that involve the transfer of payload data in addition to ordinary voice, thereby requiring the determination of session parameters.

A great number of sophisticated new mobile terminals are also becoming available on the market which are equipped with functions and capabilities to match the new services. As a result, different terminals will likely have different capabilities with respect to, e.g., codecs (coders/decoders), presentation functionality and transmission rates. The term “terminal” will be used in this description to broadly represent any type of communication station, or a common network node handling communication with a group of terminals in a conference call, typically referred to as a Multipoint Conference Unit (MCU). Thus, in terms of a session setup, this node appears more or less as a normal “terminal” to terminals participating in the conference call.

A problem that inevitably arises is that the prerequisites for each specific session using multimedia services will no longer be fixed and known in beforehand, but will vary depending on the invoked service and the capabilities of the calling and called terminals, respectively, as well as other factors. During a session, certain so-called session parameters must be used by both the calling and called terminals in order to communicate the desired information. Such session parameters define the rules of communication and may be related to available codecs and multiplexing schemes, which will be described in more detail below.

The session parameters may further depend on predefined user preferences and subscription terms, which may be tailor-made for each subscriber or defined for specific groups or categories of subscribers. In order to establish a session between terminals involving multimedia services, the session parameters must therefore first be selected and determined in a session setup procedure, before the actual session or call can begin, using those session parameters. Therefore, various protocols have been developed and standardized to execute the session setup procedure. Moreover, the session parameters can be changed at any time during the session, e.g. due to changed services requirements such as when the call switches between multimedia and pure voice.

FIG. 1 illustrates schematically a typical communication scenario between two terminals A and B. In this case, terminal A is a mobile telephone being wirelessly connected to a mobile access network 100, e.g. a WCDMA network. On the other side, terminal B is a fixed telephone being connected to a fixed access network 102, e.g. a PSTN (Public Switched Telephony Network). The two access networks 100 and 102 are in turn connected to a general “backbone” network 104, which in practice may be any type of communication network, or combination of different networks. It is assumed in this example that the networks 100, 102 and 104 use more or less known transport techniques, and therefore need no further description in this context.

In the present example, terminal A calls terminal B in order to have a multimedia call involving two-way transmission of both video and audio information. Each terminal A, B is equipped with a viewing screen Sa and Sb, respectively, and both are capable of communicating and presenting real-time video and audio. In that respect, the capabilities of the terminals A and B are fairly similar. However, they will most likely have different capabilities regarding codecs and multiplexing, as explained above, and each terminal has no knowledge of the other, initially. Therefore, the terminals A and B must exchange information regarding their specific capabilities and preferences, in order to negotiate and agree on suitable common session parameters that both can use during the forthcoming call session. In particular, the terminals must select coding/decoding schemes (i.e. codec types), and agree on a multiplexing scheme for mixing different data streams for video and audio information on a given physical channel, such that the available bandwidth is utilized in a suitable way.

H.324 is a standard defined by the International Telecommunication Union Telecommunications Sector (ITU-T) for multimedia telephony involving real-time video and audio. H.324 has been designed to handle such communication in a flexible way between terminals having differentiated capabilities, and also allowing the use of a great variety of different services. In particular, a specification called 3G-324M has been defined, based on H.324, to support real-time communication of wireless multimedia services over existing circuit-switched wireless networks. Although the present invention is not limited or restricted by any procedures specified in H.324, this standard will be referred to as an example of how a multimedia call can be established according to a current solution.

Thus, before a multimedia call between terminals A and B can begin, a communication session must be established and the session parameters to use in the call must be determined. According to H.324, establishing a communication session is divided into two procedure parts including a “bearer setup” phase and a “session setup” phase.

In the bearer setup phase, a physical communication channel is reserved throughout the communication path between the terminals A, B in both directions. The physical channel may be similar or different in the two directions, depending on whether the call is symmetric or asymmetric. A physical end-to-end channel typically comprises a series of paths through different intermediate networks, e.g. radio channels and/or fixed circuit switched voice or data channels. The details of the bearer setup phase are well-known in this field and will not be described here further.

When a physical channel has been established for the forthcoming call, the session setup phase can be executed, which is a kind of negotiation performed only by the two terminals, without involving any intermediate network node. If an intermediate MCU is involved for a conference call, the MCU is considered as the equivalent of a terminal in the following. The session setup phase is executed in order to determine the above-mentioned session parameters that both terminals are capable of using during the call session. Hence, it is entirely up to the terminals how to utilize the given physical channel. The session setup phase typically comprises several steps, such as: 1) exchange of terminal capabilities, 2) master-slave determination, 3) selecting a multiplexing scheme, and 4) opening of logical channels. These procedure steps, basically as dictated by the H.324 standard, will now be briefly described with reference to the flow chart in FIG. 2.

In a first step 200, terminal capabilities are exchanged where each terminal sends to the other terminal at least a list comprising the codec types and a set of multiplex parameters that the terminal can handle, thereby advertising its capabilities. In H.324, such information is sent in a “TCS” (Terminal Capability Set) message, and each receiving terminal must acknowledge receipt thereof. This message can be sent again at any time during the session for updating the terminal capabilities.

Master-slave determination is a necessary procedure for appointing one terminal as master and the other terminal as slave, in a next step 202, e.g. in order to avoid signalling conflicts in the communication dialogue during the session setup. According to H.324, each terminal generates a 24-bit random number called “SDN” (Status Determination Number) which is transmitted in an “MSD” (Master-Slave Determination) message, which must be acknowledged as well by the receiving terminal. A comparison of the two SDNs then unambiguously decides the master-slave appointments, according to some predefined rule. The master-slave appointments may also be used during the actual session as well, when needed.

A plurality of multiplexing schemes have preferably been defined to control how plural information streams can be multiplexed in different ways into a single bitstream to be transmitted over the physical channel established in the bearer setup phase. A multimedia call typically requires at least three separate information streams for audio, video and control information, respectively, and optionally for other data, each requiring at least one logical channel. The ratio between the different streams can be varied dynamically, depending on the needs for transmission in each stream, in order to optimally utilize the available bandwidth, i.e. the given physical channel. In H.324 for example, a multiplexing standard called H.223 is used which defines different multiplex tables controlling the allocation of various streams of audio, video, data and control information in predefined data sequences called packets. Any number of logical channels may be used, out of a limited number of possible channels, as specified by the multiplex table.

Each packet may contain a variable pattern of fields allocating the logical channels into bit positions within the packet, and the channel allocation pattern may differ from one packet to another. The total packet length may also be varied. The channel allocation scheme for each specific packet is determined by a selected multiplex table entry which may be indicated by means of a short index number included in a header of each packet. Then, it is not necessary to transmit any further overhead information regarding the multiplexing. However, the multiplex packet structure must first be defined for each index number during the session setup phase.

Thus, following the master-slave determination step 202, suitable multiplexing schemes are selected in a next step 204, when the terminals negotiate and agree on a multiplex table configuration to use during the forthcoming session. According to H.324, each terminal then sends a so-called “MES” (Multiplex table Entry Send) message, comprising a list of index numbers and the respective packet structure definitions. The receiving terminal must also acknowledge or reject each proposed index and packet structure in response to the MES message. New and updated multiplex tables may also be sent in a further MES message at any time during a session. If a packet is received having an undefined index number, that packet will be discarded by the receiving terminal.

Finally, in a step 206, all logical channels needed for the invoked service or services are established or “opened” according to the terminal capabilities which have been found common to both terminals. Preferably, a highest priority codec that both terminals can use for each specific media stream during the session is selected for that stream. According to H.324, one or both terminals send one or more so-called “OLC” (Open Logical Channel) messages to the other terminal, each message containing a proposed codec, preferably adhering to indicated priorities with respect to the TCS message received from the other terminal in step 200. Each receiving terminal may then accept or reject the proposed codec or codecs, by acknowledging or rejecting appropriate OLC messages, depending on its own capabilities and/or preferences. When the terminals have finally agreed to use a specific codec, or set of codecs, corresponding logical channels are established, and the actual session or multimedia call can begin.

The above-described example illustrates how certain communication conditions or terms, as defined by means of session parameters, can be determined before a call is executed, and/or may be changed at any time during an ongoing call. It should be noted that the order of steps 202 and 204, as well as the order of steps 204 and 206, respectively, may be reversed depending on the implementation.

The term “session parameters” is used here to generally represent any specifics determining how specific information should be communicated and interpreted. The example described above was focused on session parameters related to codecs, and multiplexing schemes. However, other important session parameters may be required, such as a parameter relating to error correction/protection which is typically included in the OLC message according to a standard H.245, which is a part of the H.324 standard.

FIG. 3 illustrates how a session can be established in a setup procedure according to the above-described H.324 standard. A calling terminal A first sends a TCS message 300 to the called terminal B. The first field 302 in the message 300 is a header field indicating that this is a TCS message. That first field is followed by a number of fields, generally indicated with the numeral 304, containing various proposed codecs etc, as normally specified in a TCS message. The arrows below indicates the various further messages being exchanged between the terminals A and B during a H.324 setup procedure.

However, it takes some time to execute the above-described bearer setup and session setup procedures, which is a serious drawback. The bearer setup phase duration has been measured to be in the range of 7 to 14 seconds for establishing a call between two mobile terminals, but can probably be reduced to approximately 5 seconds if the presently available methods are made more efficient. The session setup phase duration has been measured to be in the range of 4 to 7 seconds for existing products. Since the session setup phase takes place after the bearer setup phase, the total delay before a new call can begin will actually be at least in the range of 9-21 seconds. Similarly, when the session parameters are to be changed during an ongoing call, it will take several seconds before the terminals actually can begin to use them.

Hence, these long delays are a considerable drawback, since they reduce the attraction of multimedia services. The delays become even more tiresome if the service mode is changed during an ongoing session, such as when repeatedly switching between video mode and voice-only mode. The above-described time consuming setup procedure must then be repeated at each switching of service modes. In addition, the many messages exchanged in the session setup results in a corresponding number of round-trip delays, which particularly may be a problem when wireless links are involved where one round-trip takes approximately 0.5 s.

It is generally desirable to minimise delays and bandwidth consumption imposed by session establishment or parameter re-negotiation. It is difficult to reduce the duration of the session setup phase without substantially revising the standard, since it includes many different steps that must be executed consecutively, such as the steps illustrated in FIG. 2, involving several round-trip delays, among other things. This phase can be further delayed if the quality of the established and currently used physical channel is bad, resulting in bit errors in the transmitted data and the need for retransmissions. In particular, messages containing terminal capabilities, such as the TCS message in H.324, are typically quite long and will cause considerable delay if retransmitted. Such long messages can be divided into several segments that may be retransmitted separately.

In general, similar problems may exist for any type of session setup where the channel carrying the signalling messages is either subject to long round-trip delays, or have a narrow bandwidth compared to the amount of information transferred, or both, in combination with requiring plural round-trips to establish the session or re-negotiate parameters for an ongoing session. One example of another specification for session setup where these problems also may occur is SIP, “Session Initiation Protocol” (IETF RFC 3261 et al.). SIP is an application-layer control (signalling) protocol for creating, modifying and terminating sessions with one or more participants. These sessions include Internet multimedia conferences, Internet telephone calls and multimedia distribution.

Hence, a solution is needed for reducing the current long delays involved with the setup of sessions requiring the determination of parameters, e.g. in multimedia calls. In particular, it is desirable to still use presently defined routines and standards, not requiring any new standard specifications and preferably using existing sets of signalling messages.

The international patent application PCT/SE03/01901 describes a solution for avoiding a regular time-consuming session setup procedure in the case when two terminals have executed a multimedia call previously. The terminals are then required to store the session parameters such that they can be retrieved from a storage means in each terminal and be used again in a following call, assuming that those parameters are still valid. Potential drawbacks in this solution are: 1) the prerequisite that the terminals have made a similar call previously, and 2) they must store used session parameters after each executed call, requiring a writable memory with a certain storage capacity in each terminal.

### SUMMARY OF THE INVENTION

The object of the present invention is to reduce or eliminate the problems outlined above. This object and others are obtained by providing a method and apparatus for determining session parameters to be used during a communication session between a first terminal and a second terminal, as outlined below.

According to the inventive method, at least the first terminal has stored at least one default set of session parameters. In order to negotiate the session parameters to be used, the first terminal sends to the second terminal an identifier corresponding to a proposed default set of session parameters, which are thus available in the first terminal. It is then determined whether the second terminal accepts the proposed default set of session parameters or not, which is the case if it has recognized the identifier and also has the proposed session parameters stored.

If the second terminal has accepted the proposed default set of session parameters, they are retrieved by both terminals from their respective storage means in order to execute the session based on the retrieved parameters. On the other hand, if the second terminal has not accepted the proposed default set of session parameters, the terminals will fall back to a regular session setup procedure, e.g. as the one described in the background section.

The session parameters can be determined as above to either establish a new session, or re-negotiate parameters for an ongoing session. The session is typically a multimedia session, requiring the determination of such session parameters to enable the transfer of separate media streams for at least audio and video.

In one embodiment, the default set identifier may be included in a session initiating message sent from the first terminal to the second terminal, said message further including at least one specific session parameter as normally occurring in a regular first session setup message. Thereby, an acknowledging message will be received from the second terminal in response to the session initiating message, regardless of whether it can accept the proposed parameters or not.

The first terminal can then determine whether the second terminal accepts the proposed default set of session parameters or not by monitoring the behaviour of the second terminal after receiving the acknowledging message. Thus, if the second terminal starts to send media indicating that the proposed default set of session parameters has been accepted, the session is executed. On the other hand, if the second terminal continues signalling according to a regular setup procedure indicating that the proposed default set of session parameters has not been accepted, said regular session setup procedure can be executed by using the exchanged session initiating message as the first session setup message, thereby saving one roundtrip delay.

In the inventive method, messages according to the ITU-T standard H.324 may be used, and the default parameters set identifier may then be included in a TCS message.

The apparatus according to the present invention is a first terminal capable of determining session parameters to be used during a communication session with a second terminal, and having stored at least one default set of session parameters. The first terminal comprises means for sending to the second terminal an identifier corresponding to a proposed default set of session parameters, and means for determining whether the second terminal accepts the proposed default set of session parameters or not. The first terminal further comprises means for retrieving the proposed default set of session parameters in order to execute the session based on the retrieved parameters if the second terminal has accepted the proposed default set of session parameters, and means for falling back to a regular session setup procedure if the second terminal has not accepted the proposed default set of session parameters.

In one embodiment, the first terminal may be adapted to send a session initiating message including the default set identifier, and also including at least one specific session parameter as normally occurring in a regular first session setup message. The terminal may further be adapted to determine whether the second terminal accepts the proposed default set of session parameters or not by monitoring the behaviour of the second terminal. The first terminal is then also adapted to execute a regular session setup procedure by using the exchanged session initiating message as the first session setup message, if the second terminal has not accepted the proposed default set of session parameters. The first terminal may further be adapted to use the ITU-T standard H.324.

The present invention results in reduced delays and a minimum of bandwidth consumption for establishment or re-negotiation of session parameters, e.g. in multimedia calls. Furthermore, it will be possible to still use presently defined routines, standards and existing sets of signalling messages, without requiring that existing standard specifications are changed.

### BRIEF DESCRIPTION OF THE DRAWINGS

The present invention will now be described in more detail and with reference to the accompanying drawings, in which:

FIG. 1 is a schematic view of a communication scenario for executing a video call between two terminals.

FIG. 2 is a flow chart illustrating a session setup phase during a session establishment procedure, according to the prior art.

FIG. 3 is a communication diagram illustrating the session setup, according to the prior art.

FIG. 4 is a communication diagram illustrating the session setup if the called terminal accepts default parameters, in accordance with one embodiment.

FIG. 5 is a communication diagram illustrating a fallback to a regular session setup.

FIG. 6 is a flow chart generally illustrating a session establishment procedure, e.g. according to the embodiment in FIGS. 4 and 5.

FIG. 7 is a communication diagram illustrating two alternatives of a session establishment procedure, in accordance with another embodiment.

FIG. 8 is a flow chart generally illustrating another session establishment procedure, e.g. according to the embodiment in FIG. 7.

FIG. 9 is a block diagram schematically illustrating a first terminal setting up a communication session with a second terminal, in accordance with another embodiment.

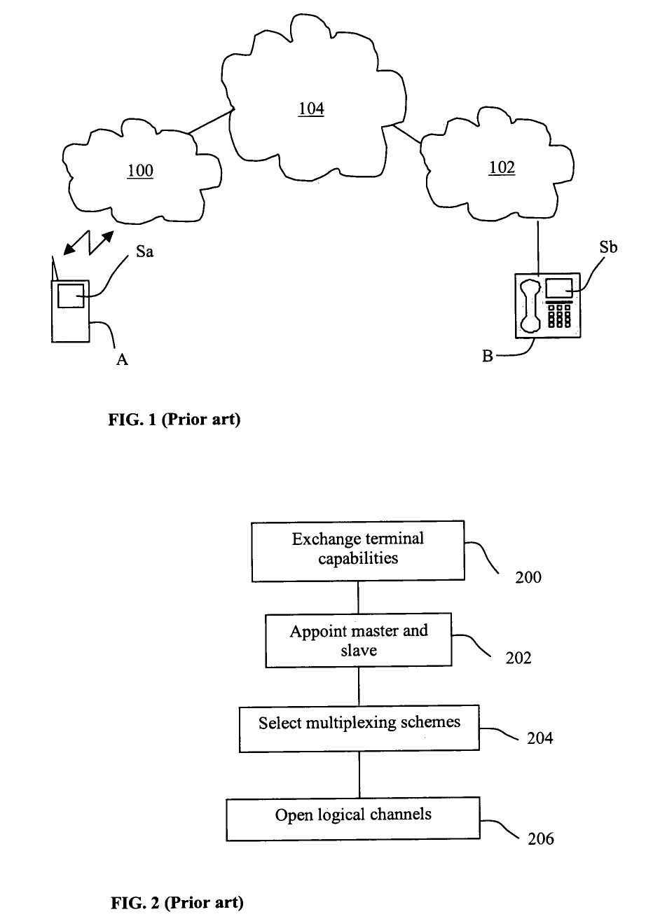

### DESCRIPTION OF PREFERRED EMBODIMENTS

When a requested call or session requiring the determination of session parameters shall be established between two terminals, such as for a multimedia call, the procedure of determining session parameters can be substantially simplified and the delay caused by the session setup can be reduced, if those two terminals have executed a similar session previously according to the solution described in the above-mentioned PCT/SE03/01901. However, the present invention generally provides an alternative solution not requiring that the terminals have executed a session previously, nor that they possess a writable memory. This solution can also be applied in order to change, or re-negotiate, the session parameters during an ongoing session, e.g. if the services used are changed.

Briefly described, if each terminal has stored at least one default set of session parameters in beforehand, they can execute the session by retrieving and using such a default set of parameters, without first negotiating the details of those parameters in a time-consuming regular setup procedure. The terminals will then only need to agree on using a specific default set of session parameters which is stored in both terminals, requiring a minimum of message exchanging between the terminals before the session can start and use the session parameters. Thereby, a much faster session setup can be obtained as compared to the regular procedure.

In some cases, the selected default set of parameters may not be fully optimal for that particular session, but the session may at least be started very quickly if both terminals can initially accept them and “default media” can be presented to the end-users. After the session start, new parameters can always be re-negotiated by means of currently available signalling protocols during the ongoing session, if needed, e.g. within a few seconds from the start. Further, if another default set of session parameters should turn out to be more suitable for the already-started session, e.g. due to a change of used services, it is possible to utilize the present invention to quickly change to the other set, as will be described below.

FIGS. 4 and 5 are diagrams illustrating the signalling between two terminals A and B according to one embodiment of the invention. In this example, the terminals A, B are adapted to basically use the H.324 standard to establish and execute multimedia calls, although it would be possible to use any suitable standard available. In addition, and in accordance with the present solution, each terminal has stored in beforehand a number of default sets of session parameters which can be retrieved quickly for use in a session as follows. For each default set, a corresponding identifier has also been stored. These default parameter sets can be stored in a limited fixed storage means in each terminal, which is relatively simpler and cheaper than the writable memory required for the solution described in PCT/SE03/01901.

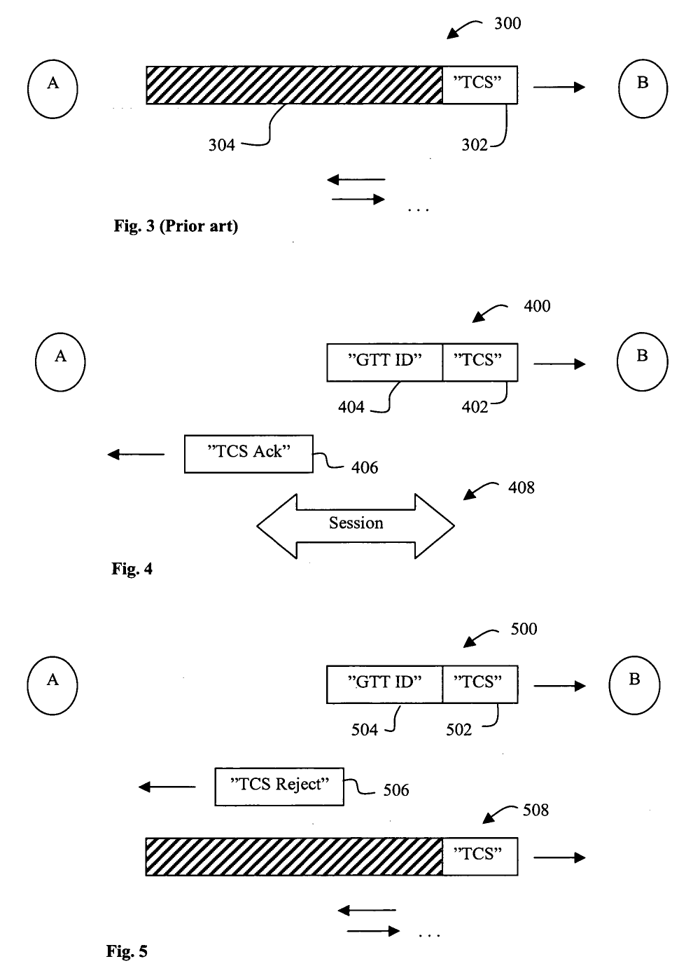

The H.324 standard prescribes that the first message to be sent from the calling terminal A is a TCS message, as described above in connection with FIGS. 2 and 3. Therefore, terminal A starts by sending a TCS message 400 to terminal B accordingly, as shown in FIG. 4. As in FIG. 3, the first field 402 in the message 400 is a short header field indicating that this is a TCS message.

However, instead of including in the TCS message further fields containing lengthy parameter specifications for proposed codecs etc., as indicated by the numeral 304 in FIG. 3, a new field 404 is included in the message 400, containing a short identifier for a proposed default set of session parameters. Terminal A is configured to select from its memory the most suitable default set to propose, depending on the characteristics of the forthcoming session, involving specific media types. Here, the proposed default set is indicated by means of a suitable identifier “GTT ID”, which stands for “Generic Terminal Type Identity”. In order to make the TCS message as short as possible, each stored default set has been assigned a generally known identity code GTT ID that any terminal having that default set stored will be able to recognize as its identifier. According to this embodiment, the message 400 basically includes only these two fields 402, 404, thus making the message significantly shorter than the regular TCS message 300 in FIG. 3.

When the called terminal B receives the message 400, it can recognize message 400 as a TCS message by reading the first field 402, and, by reading the next field 404, that the calling terminal A is proposing a specific default set of session parameters, as indicated by the GTT ID. Terminal B then compares the received GTT ID with its stored GTT ID's. If it find's a match between the received GTT ID and one of the stored ones, the proposed set can be retrieved for use in the session. In this example, terminal B thus responds by sending an acknowledgment message 406, indicating to terminal A that the proposed set of session parameters is accepted. Thereafter, the session can immediately begin, as indicated by the numeral 408. This quick setup procedure requires only one round-trip delay, thereby saving much time and bandwidth as compared to a regular setup.

FIG. 5 illustrates a similar scenario where terminal A starts by sending a TCS message 500 including a first TCS indicating field 502 and a following field 504 with a proposed GTT ID. However in this case, terminal B is not able to use the proposed default set, either because it does not have that specific set stored, i.e. cannot find a match in its memory, or because it does not at all understand this TCS message having the GTT ID in the field 504 instead of a series of proposed codecs. Therefore, terminal B sends in response a reject message 506 to terminal A. From this message, terminal A concludes that a regular session setup procedure must be executed, instead of using the proposed default set of parameters. Therefore, the procedure falls back to the regular setup by terminal A sending a regular TCS message 508, of the kind described in connection with FIGS. 2 and 3, followed by further exchange of messages indicated by the arrows further down in FIG. 5.

Alternatively, terminal A may make a further attempt to propose another default set of parameters by sending a second TCS message, not shown, including a corresponding GTT ID. Then, terminal B may find a match for the newly proposed GTT ID, and can send an acknowledgment message in response thereto in order to start the session after this second round-trip. Otherwise, it will send another reject message initiating a fallback to the regular procedure, although further delayed by the extra round-trip. Evidently, there is a risk that the session setup becomes more and more delayed for each new attempt for a quick setup are made by terminal A, and it may be recommendable that only one such attempt is made.

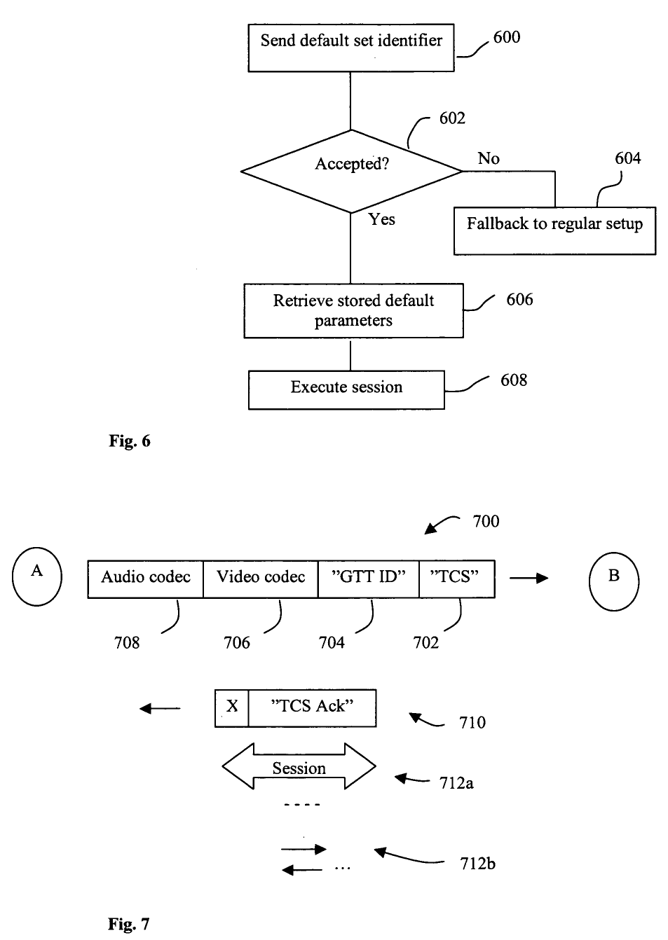

FIG. 6 is a flow chart illustrating a procedure for establishing a multimedia session, or re-negotiating an ongoing one, between a first terminal and a second terminal according to one embodiment, as exemplified by FIGS. 4 and 5. In this embodiment, the present invention is implemented at least in the first terminal. In a first step 600, the first terminal sends a session initiating message containing a proposed default parameter set identifier, such as the above-described GTT ID, to the second terminal. The session initiating message may be used to either establish a new session or re-negotiate parameters for an ongoing session, as described above.

In a next step 602, it is determined whether the second terminal has accepted the proposed set of parameters, e.g. by receiving either an acknowledgment message (Yes) or a reject message (No), as described above. If not accepted, the procedure falls back to a regular session setup in a step 604, e.g. as described in connection with FIG. 5. However, if the second terminal has sent a message indicating acceptance, parameters of the proposed default set are retrieved, in a step 606, by both terminals from their respective storage means. Thereafter, the session can be executed using the retrieved parameters, in a final step 608.

FIG. 7 illustrates a signalling procedure between two terminals A and B according to another embodiment of the invention. Also in this example, the terminals A, B are adapted to use the H.324 standard for multimedia calls, and at least terminal A has stored in beforehand a number of default sets of session parameters along with corresponding identifiers GTT ID's.

Terminal A begins by sending a TCS message 700 as a session initiating message to terminal B, containing a TCS indication field 702 and a field 704 with a proposed GTT ID. However in this embodiment, the TCS message 700 also contains one or more further fields identical to a single set of preferably mandatory codecs including any further required parameters to constitute a fully valid regular TCS message. In this example, two fields 706 and 708 are included specifying a proposed audio codec and a proposed video codec, respectively. However, any parameters may be included in the TCS message 700, as long as they make up a regular first session setup message.

By including fields 706, 708 with the proposed audio and video codecs, the other terminal will be able to properly recognize the received TCS message even if it is not adapted to use the inventive quick setup procedure, by means of those fields which are included in a normal first TCS message. Therefore, terminal B will be more or less guaranteed to respond by sending an acknowledging message in any case.

Basically, two situations may now occur. On one hand, terminal B may recognize and accept the proposed GTT ID. On the other hand, terminal B may either not at all recognize the proposed GTT ID but recognizes the received TCS message 700 as a regular first TCS message, or may recognize but not accept the proposed GTT ID after not finding a matching GTT ID in its memory. In any case, terminal B therefore sends an acknowledging message 710 regardless of whether it has accepted the proposed GTT ID or not.

After reception of the acknowledging message, it is possible for terminal A to determine from the behaviour of terminal B whether to use the proposed default set or not. If terminal B did not recognize/accept the received GTT ID, it will continue signalling according to the regular setup procedure. Thus, if terminal B has indeed recognized and accepted the GTT ID, it will start sending media so that the session 712a can immediately begin after the acknowledging message 710. However if not accepted, terminal B will still be able to use the received TCS message 700 as the first message in a regular setup procedure which thereby can continue from there, as indicated by arrows 712b.

In this way, one round-trip has been saved by being able to utilize the quick setup proposal as the first message in a regular procedure, if the quick setup cannot be fulfilled. As mentioned above, it is generally possible to include any parameter(s) in the TCS message 700, including multiplex parameters, in order to make it useful as a proper first session setup message, but the audio and video codecs are the most common parameters to specify at present.

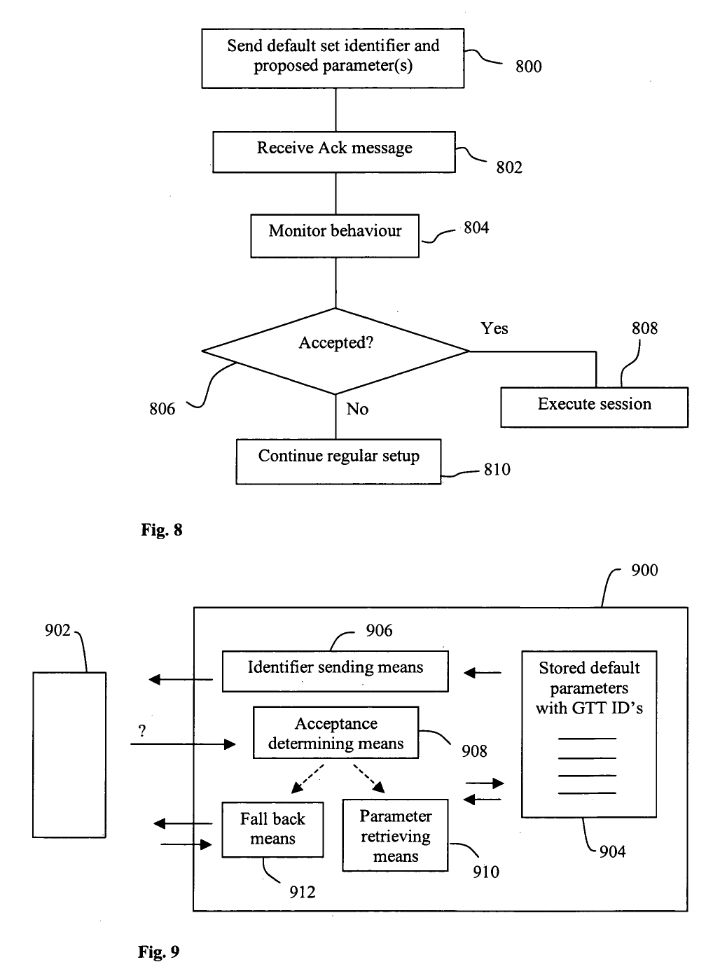

FIG. 8 is a flow chart illustrating a modified procedure to set up a multimedia session between two terminals, e.g. as exemplified by the embodiment in FIG. 7. Here also, the present invention is implemented in at least a first terminal. In a first step 800, the first terminal sends a session initiating message to a second terminal containing a proposed default parameter set identifier, as well as at least one specific session parameter as normally occurring in a regular first session setup message.

In a next step 802, an acknowledging message is received from the second terminal, such as the message 710 in FIG. 7. Next, the behaviour of the second terminal is monitored by the first terminal in a step 804, e.g. as described in connection with FIG. 7. Then, it is determined in a step 806 from the monitored behaviour whether the second terminal has accepted the proposed default set of parameters or not. If accepted, the session is executed in a step 808, based on the proposed and accepted default parameters. However, if the proposed default parameter set is not accepted by the second terminal, the procedure falls back to continuing a regular session setup in a step 810, using the already-exchanged first session setup message containing the proposed parameter(s). Hence, the regular setup has effectively started in step 800 and continues in step 810 by using the exchanged session initiating message as the proper first session setup message.

FIG. 9 is a block diagram schematically illustrating a first terminal 900 setting up a communication session with a second terminal 902, according to an embodiment of the present invention. The first terminal 900 has stored at least one default set of session parameters 904 together with identifiers corresponding to each default set. Terminal 900 further comprises means 906 for sending to the second terminal 902 an identifier corresponding to a proposed default set of session parameters. Terminal 900 further comprises means 908 for determining whether the second terminal accepts the proposed default set of session parameters or not, depending on how terminal 902 reacts to the proposed default set, as described above. Terminal 900 further comprises means 910 for retrieving the proposed default set of session parameters in order to execute the session based on the retrieved parameters, if the second terminal has accepted the proposed default set of session parameters. Terminal 900 further comprises means 912 for falling back to a regular session setup procedure if the second terminal has not accepted the proposed default set of session parameters.

As described above, the quick session setup can work if both terminals have the proposed default set of parameters stored. Thus, each terminal may have stored a number of such default sets of parameters as exemplified in the table below:

| GTT ID | Audio codec | Video codec |
|---|---|---|
| 1a | AMR | H263 baseline |
| 1b | AMR | MPEG-4 |
| 1c | G. 723 | H263 baseline |
| 1d | G. 723 | MPEG-4 |

This table contains different possible audio and video codec combinations for generic terminal types according to the standard 3G-324M, Release 5. It is also possible to store further default sets valid for other standards and/or releases, e.g. with GTT ID's 2a, 2b, 2c . . . for 3G-324M, Release 6. Moreover, each default set may of course include several other session parameters in addition to the audio and video codecs exemplified above, and the present invention is not limited in this respect.

In the present invention, as exemplified by means of the above-described embodiments, the delays and bandwidth consumption involved during session establishment or re-negotiation of parameters can be substantially reduced by using a minimum of messaging between the two communicating terminals.

While the invention has been described with reference to specific exemplary embodiments, the description is only intended to illustrate the inventive concept and should not be taken as limiting the scope of the invention. Various alternatives, modifications and equivalents may be used without departing from the spirit of the invention, which is defined by the appended claims.

1. A method of determining session parameters to be used during a communication session between a first terminal and a second terminal, wherein at least the first terminal has stored at least one default set of session parameters, the method comprising the following steps:
A) sending from the first terminal to the second terminal an identifier corresponding to a proposed default set of session parameters,
B) determining whether the second terminal accepts the proposed default set of session parameters or not, and
C) retrieving the proposed default set of session parameters in order to execute the session based on the retrieved parameters, if the second terminal has accepted the proposed default set of session parameters, or
D) falling back to a regular session setup procedure if the second terminal has not accepted the proposed default set of session parameters.

2. A method according to claim 1, wherein the session parameters are determined to establish a new session.

3. A method according to claim 1, wherein the session parameters are determined to re-negotiate parameters for an ongoing session.

4. A method according to claim 1, wherein the session is a multimedia session.

5. A method according to claim 1, wherein the default set identifier is included in a session initiating message sent from the first terminal to the second terminal, said message further including at least one specific session parameter as normally occurring in a regular first session setup message.

6. A method according to claim 5, wherein an acknowledging message is received from the second terminal, in response to the session initiating message.

7. A method according to claim 6, wherein the first terminal determines whether the second terminal accepts the proposed default set of session parameters or not by monitoring the behaviour of the second terminal after receiving the acknowledging message.

8. A method according to claim 7, wherein the session is executed if the second terminal starts to send media indicating that the proposed default set of session parameters has been accepted.

9. A method according to claim 7, wherein, if the second terminal continues signalling according to a regular setup procedure indicating that the proposed default set of session parameters has not been accepted, said regular session setup procedure is executed by using the exchanged session initiating message as the first session setup message.

10. A method according to claim 1, wherein messages of the ITU-T standard H.324 are used in the method.

11. A method according to claim 10, wherein the default parameters set identifier is included in a TCS message.

12. A first terminal capable of determining session parameters to be used during a communication session with a second terminal, wherein the first terminal has stored at least one default set of session parameters, and comprises:
means for sending to the second terminal an identifier corresponding to a proposed default set of session parameters,
means for determining whether the second terminal accepts the proposed default set of session parameters or not, and
means for retrieving the proposed default set of session parameters in order to execute the session based on the retrieved parameters, if the second terminal has accepted the proposed default set of session parameters, and
means for falling back to a regular session setup procedure if the second terminal has not accepted the proposed default set of session parameters.

13. A terminal according to claim 12, wherein the first terminal is adapted to send a session initiating message including the default set identifier, and further including at least one specific session parameter as normally occurring in a regular first session setup message.

14. A terminal according to claim 13, wherein the first terminal is adapted to determine whether the second terminal accepts the proposed default set of session parameters or not by monitoring the behaviour of the second terminal.

15. A terminal according to claim 14, wherein the first terminal is adapted to execute a regular session setup procedure by using the exchanged session initiating message as the first session setup message, if the second terminal has not accepted the proposed default set of session parameters.

16. A terminal according to claim 12, wherein the first terminal is adapted to use the ITU-T standard H.324.
